(19) United States
(12) Patent Application Publication
(10) Pub. No.: US 2010/0224767 A1
(43) Pub. Date: Sep. 9, 2010

(54) PHOTODETECTOR, METHOD FOR MANUFACTURING THE SAME, AND PHOTODETECTION SYSTEM

(75) Inventors: Noriyuki KAWANO, Tokyo (JP); Tetsuya NISHIYAMA, Tokyo (JP); Hironobu NISHIMURA, Tokyo (JP); Tomohiko ISHIDA, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/715,038

(22) Filed: Mar. 1, 2010

(30) Foreign Application Priority Data
Mar. 4, 2009 (JP) 2009-051116

(51) Int. Cl. H01L 31/0232; H01L 31/09; H01L 31/0216; H01L 31/18

(52) U.S. Cl. 250/216; 257/435; 438/64; 257/E31.122

(57) ABSTRACT

A photodetector used in, for example, an optical pickup device includes: a photodetection unit including a plurality of photodetection elements and provided on a semiconductor chip; a light transmitting unit formed on the upper surface of the photodetection unit; and a light shielding layer having an optical aperture and disposed on the upper surface of the light transmitting unit, with these components being formed integrally. The light transmitting unit is configured such that the distance between the optical aperture and the photodetection unit is maintained constant, and the optical aperture is formed such that the inner portion of an incident light beam passes therethrough. The positioning of the photodetector and the positioning of the optical aperture such as a pinhole or a slit for adjusting the light beam entering the photodetection elements of the photodetector can be made at the same time.

### BACKGROUND OF THE INVENTION

1. Field of the Invention

The present invention relates to a photodetector, and in particular to a photodetector suitably used in an optical head device for recording and reproducing information on and from an optical recording medium, to a method for manufacturing the photodetector, and to a photodetection system using the photodetector.

2. Description of the Related Art

Japanese Patent Application Laid-Open No. Hei 8-185640 discloses an optical pickup device for a dual-layer optical disc that can detect servo signals accurately to perform control operations in a reliable manner.

This optical pickup device is configured to include: a photodetector that receives a light beam reflected from a dual-layer optical disc; a beam splitter; a first focusing lens that is disposed between the photodetector and the beam splitter such that their optical axes coincide with each other; a light shielding plate that shields the beam reflected from an unfocused information signal layer; and a second focusing lens. This device is configured such that the beam reflected from the unfocused information signal layer, i.e., interlay stray light, is prevented from reaching the photodetector so that servo signals are detected accurately.

However, in the optical pickup device described in the above Japanese Patent Application Laid-Open No. H08-185640, the positioning of the photodetector and the positioning of a pinhole must be performed separately when the device is assembled. Therefore, the positioning is difficult and time consuming. In addition, the mass production of the device is difficult.

### SUMMARY OF THE INVENTION

In view of the foregoing problems, various exemplary embodiments of this invention provide a photodetector which enables the positioning of the photodetector and the positioning of an optical aperture such as a pinhole to be made at one time when an optical head is assembled, so that the optical head can be mass-produced with high precision at low cost. Various exemplary embodiments of this invention further provide a method for manufacturing this photodetector and a photodetection system using the photodetector.

In summary, the above-described objectives are achieved by the following embodiments of the present invention.

(1) A photodetector, comprising: a semiconductor chip; a photodetection unit formed as a part of the semiconductor chip; a light transmitting unit disposed on a detection side of the at least one photodetection unit; and a light shielding layer for shielding an incident light beam, the light shielding layer being disposed on the light transmitting unit on a side opposite to the photodetection unit, the light shielding layer having an optical aperture that is formed such that the incident light beam passes therethrough and reaches the photodetection unit through the light transmitting unit, wherein the semiconductor chip, the photodetection unit, the light transmitting unit, and the light shielding layer are formed integrally, and a size of the optical aperture and a position of the optical aperture relative to the photodetection unit are set such that an inner portion of a cross section of the incident light beam passes through the optical aperture and that the incident light beam having an expanded cross-sectional area is projected within a light receiving surface of the photodetection unit, the expanded cross-sectional area of the incident light beam depending on a thickness of the light transmitting unit.

(2) The photodetector according to (1), wherein the photodetection unit comprises a plurality of photodetection units, and the optical aperture comprises a plurality of optical apertures that correspond to the plurality of photodetection units.

(3) The photodetector according to (1) or (2), wherein the light transmitting unit is a light transmitting material layer that is deposited so as to cover a surface of the semiconductor chip including the photodetection unit, the light shielding layer is a light shielding material film that is formed on a light incident surface of the light transmitting unit, and the optical aperture is a patterned void space that is formed in the light shielding material film.

(4) The photodetector according to (1) or (2), further comprising a spacer layer that covers a surface of the semiconductor chip except for the photodetection unit, and wherein the light transmitting unit is a light transmitting space formed in the spacer layer, the light shielding layer is a light shielding material film that is formed on the spacer layer, and the optical aperture is a patterned void space that is formed in the light shielding material film.

(5) The photodetector according to (4), wherein the spacer layer is a light transmitting material layer that is deposited so as to cover the surface of the semiconductor chip except for the photodetection unit, the light transmitting space is formed by removing a part of the light transmitting material layer, and the void space in the light shielding material film is formed by removing a part of the light shielding material film.

(6) The photodetector according to any of (3) to (5), wherein the photodetection unit is a photodiode that is formed so as to be embedded in an upper surface of the semiconductor chip.

(7) The photodetector according to (1) or (2), further comprising: a substrate on which the semiconductor chip is mounted, the photodetection unit being formed as a part of the semiconductor chip disposed on the substrate; a spacer layer that covers the substrate and a surface of the semiconductor chip except for the photodetection unit; and a bonding lead wire that electrically connects the semiconductor chip to the substrate, the spacer layer containing the bonding lead wire therein so as to protect the bonding lead wire, and wherein the light transmitting unit is a light transmitting space surrounded by the spacer layer.

(8) A photodetection system, comprising: a photodetector according to any of (1) to (7); and a detection optical system that guides a reflected light beam from an optical recording medium to the photodetection unit through the optical aperture of the photodetector, wherein the optical aperture is disposed at a beam waist of the reflected light beam.

(9) A method for manufacturing a photodetector having an optical aperture and including a photodetection unit being integral with the optical aperture and a light transmitting unit, a size of the optical aperture and a position of the optical aperture relative to the photodetection unit being set such that an inner portion of a cross section of an incident light beam passes through the optical aperture and that the incident light beam having an expanded cross-sectional area is projected within a light receiving surface of the photodetection unit, the expanded cross-sectional area of the incident light beam depending on a thickness of the light transmitting unit, the method comprising the steps of: forming the light transmitting unit by depositing a light transmitting resin or glass on a semiconductor wafer to a thickness equal to a distance between the photodetection unit and the optical aperture, the semiconductor wafer including semiconductor chips each of which includes, on an upper surface thereof, the photodetection unit and an electrode that transmits an output signal from an output terminal of the photodetection unit through a wiring unit, the light transmitting unit being deposited so as to cover at least the photodetection unit; forming a photoresist layer by applying a photoresist to a surface of the light transmitting unit, the surface of the light transmitting unit being on a side opposite to the photodetection unit; exposing the photoresist layer to light through a photomask that covers a region of the photo resist layer corresponding to the optical aperture; removing an exposed portion of the photoresist layer being the region other than the region corresponding to the optical aperture by development; forming a light shielding layer made of a light shielding material on the photoresist layer from which the exposed portion has been removed and on a naked surface of the light shielding section; lifting off and removing the unexposed portion of the photoresist layer together with the light shielding material formed thereon; and cutting the semiconductor wafer into the individual semiconductor chips after the light transmitting unit, the light shielding layer and the optical aperture are formed in each semiconductor chip.

(10) A method for manufacturing a photodetector having an optical aperture and including a photodetection unit being integral with the optical aperture and a light transmitting unit, a size of the optical aperture and a position of the optical aperture relative to the photodetection unit being set such that an inner portion of a cross section of an incident light beam passes through the optical aperture and that the incident light beam having an expanded cross-sectional area is projected within a light receiving surface of the photodetection unit, the expanded cross-sectional area of the incident light beam depending on a thickness of the light transmitting unit, the method comprising the steps of: forming the light transmitting unit by depositing a light transmitting resin or glass on a semiconductor wafer to a thickness equal to a distance between the photodetection unit and the optical aperture, the semiconductor wafer including semiconductor chips each of which includes, on an upper surface thereof, the photodetection unit and an electrode that transmits an output signal from an output terminal of the photodetection unit through a wiring unit, the light transmitting unit being deposited so as to cover at least the photodetection unit; forming a photoresist layer by applying a photoresist to a surface of the light transmitting unit, the surface of the light transmitting unit being on a side opposite to the photodetection unit; exposing the photoresist layer to light through a photomask that covers a region other than the region of the photoresist layer corresponding to the optical aperture; removing an unexposed portion of the photoresist layer being the region corresponding to the optical aperture by development; forming a light shielding layer made of a light shielding material on the photoresist layer from which the unexposed portion has been removed and on a naked surface of the light shielding section; lifting off and removing the exposed portion of the photoresist layer together with the light shielding material formed thereon; and cutting the semiconductor wafer into the individual semiconductor chips after the light transmitting unit, the light shielding layer and the optical aperture are formed in each semiconductor chip.

(11) A method for manufacturing a photodetector having an optical aperture and including a photodetection unit being integral with the optical aperture and a light transmitting unit, a size of the optical aperture and a position of the optical aperture relative to the photodetection unit being set such that an inner portion of a cross section of an incident light beam passes through the optical aperture and that the incident light beam having an expanded cross-sectional area is projected within a light receiving surface of the photodetection unit, the expanded cross-sectional area of the incident light beam depending on a thickness of the light transmitting unit, the method comprising the steps of: forming a first photoresist layer having a thickness equal to a distance between the photodetection unit and the optical aperture by applying a first photoresist to a surface of a semiconductor wafer, the surface being opposite to a substrate, the semiconductor wafer including semiconductor chips each of which includes, on an upper surface thereof, the photodetection unit and an electrode that transmits an output signal from an output terminal of the photodetection unit through a wiring unit, a first photoresist layer being deposited so as to cover at least the photodetection unit; exposing the first photoresist layer to light through a first photomask that covers a region of the first photoresist corresponding to the photodetection unit; removing an unexposed portion of the first photoresist layer by development to form a light transmitting space and a spacer layer surrounding the light transmitting space; providing a light transmitting cover glass layer so as to cover a surface of the spacer layer and the light transmitting space; forming a second photoresist layer by applying a second photoresist to a surface of the cover glass layer; exposing the second photoresist layer to light through a second photomask that covers a region of the second photoresist layer corresponding to the optical aperture; removing an exposed portion of the second photoresist layer by development; forming a light shielding layer made of a light shielding material on an unexposed portion of the second photoresist layer and on a naked surface of the cover glass layer from which the exposed portion are removed; lifting off and removing the unexposed portion of the second photoresist layer together with the light shielding material formed thereon; and cutting the semiconductor wafer after a light transmitting unit, the light shielding layer and the optical aperture are formed in each semiconductor chip.

(12) A method for manufacturing a photodetector having an optical aperture and including a photodetection unit being integral with the optical aperture and a light transmitting unit, a size of the optical aperture and a position of the optical aperture relative to the photodetection unit being set such that an inner portion of a cross section of an incident light beam passes through the optical aperture and that the incident light beam having an expanded cross-sectional area is projected within a light receiving surface of the photodetection unit, the expanded cross-sectional area of the incident light beam depending on a thickness of the light transmitting unit, the method comprising the steps of: forming a first photoresist layer having a thickness equal to a distance between the photodetection unit and the optical aperture by applying a first photoresist to a surface of a semiconductor wafer, the surface being opposite to a substrate, the semiconductor wafer including semiconductor chips each of which includes, on an upper surface thereof, the photodetection unit and an electrode that transmits an output signal from an output terminal of the photodetection unit through a wiring unit, a first photoresist layer being deposited so as to cover at least the photodetection unit; exposing the first photoresist layer to light through a first photomask that covers a region other than the region of the first photoresist layer corresponding to the photodetection unit; removing an exposed portion of the first photoresist layer by development to form a light transmitting space and a spacer layer surrounding the light transmitting space; providing a light transmitting cover glass layer so as to cover a surface of the spacer layer and the light transmitting space; forming a second photoresist layer by applying a second photoresist to a surface of the cover glass layer; exposing the second photoresist layer to light through a second photomask that covers a region other than the region of the second photoresist layer corresponding to the optical aperture; removing an unexposed portion of the second photoresist layer by development; forming a light shielding layer made of a light shielding material on an exposed portion of the second photoresist layer and on a naked surface of the cover glass layer from which the unexposed portion are removed; lifting off and removing the exposed portion of the second photoresist layer together with the light shielding material formed thereon; and cutting the semiconductor wafer after a light transmitting unit, the light shielding layer and the optical aperture are formed in each semiconductor chip.

(13) A method for manufacturing a photodetector having an optical aperture and including a photodetection unit being integral with the optical aperture and a light transmitting unit, a size of the optical aperture and a position of the optical aperture relative to the photodetection unit being set such that an inner portion of a cross section of an incident light beam passes through the optical aperture and that the incident light beam having an expanded cross-sectional area is projected within a light receiving surface of the photodetection unit, the expanded cross-sectional area of the incident light beam depending on a thickness of the light transmitting unit, the method comprising the steps of: forming a photoresist layer having a thickness equal to a distance between the photodetection unit and the optical aperture by applying a first photoresist to a semiconductor wafer, the semiconductor wafer including semiconductor chips each of which includes, on an upper surface thereof, the photodetection unit and an electrode that transmits an output signal from an output terminal of the photodetection unit through a wiring unit, a photoresist layer being deposited so as to cover at least the photodetection unit; exposing the photoresist layer to light through a first photomask that covers a region corresponding to the photodetection unit; removing an unexposed portion of the photoresist layer by development to form a light transmitting space and a spacer layer surrounding the light transmitting space; depositing a film resist so as to cover a surface of the spacer layer and the light transmitting space, the film resist including a film and a second photoresist applied thereto, the film resist being deposited such that the film is in contact with the spacer layer; exposing only a portion of the film resist to light through a second photomask, the portion of the film resist being a region corresponding to the optical aperture; removing an exposed portion of the second photoresist of the film resist by development; forming a light shielding layer made of a light shielding material on a surface of an unexposed portion of the second photoresist layer and on a naked surface of the film; lifting off and removing the unexposed portion together with the light shielding material formed thereon; and cutting the semiconductor wafer into the individual semiconductor chips after a light transmitting unit, the light shielding layer and the optical aperture are formed in each semiconductor chip.

(14) A photodetection system, comprising: a laser light source that generates a light beam; an objective lens that focuses the light beam from the laser light source on an optical recording medium and receives a light beam reflected from the optical recording medium; an astigmatic optical element that generates astigmatism such that the reflected light beam passing through the objective lens is focused linearly in a Y direction at a front focal line located closer to the objective lens and is also focused linearly in an X direction at a rear focal line located further from the objective lens, the Y direction and the X direction being orthogonal to each other in a plane perpendicular to an optical axis of the reflected light beam, the optical axis being a Z direction; and a photodetector according to any of claims 1 to 7, wherein the photodetector is disposed between the front focal line and the rear focal line so as to detect a focal point of the objective lens from a shape of the reflected light beam, and the light shielding layer is disposed at a position of the front focal line so that part of the reflected light beam is shielded, the part of the reflected beam being outside portions thereof in a widthwise direction orthogonal to a lengthwise direction of a cross-sectional shape of the reflected light beam at the front focal line.

### BRIEF DESCRIPTION OF THE DRAWINGS

FIG. 1 is an enlarged cross-sectional view illustrating a photodetector according to a first exemplary embodiment of the present invention;

FIG. 2 is a plan view taken along line II-II in FIG. 1;

FIG. 3A is a schematic diagram illustrating an example of the cross-sectional shape of a light beam when an optical aperture shown in FIG. 1 is a pinhole;

FIG. 3B is a schematic diagram illustrating an example of the cross-sectional shape of the light beam when the optical aperture shown in FIG. 1 has a slit-like shape;

FIG. 4 is a plan view illustrating a photodetector according to a second exemplary embodiment of the present invention;

FIG. 5 is a front view of the photodetector of FIG. 4;

FIGS. 6(A) to 6(F) are partial cross-sectional front views illustrating the process of manufacturing the photodetector according to the second exemplary embodiment of the present invention;

FIGS. 7(A) to 7(C) are plan views illustrating the same manufacturing process of FIG. 6;

FIGS. 8(A) to 8(H) are partial cross-sectional front views illustrating the process of manufacturing a photodetector according to a third exemplary embodiment of the present invention;

FIG. 9 is a plan view illustrating the same manufacturing process of FIG. 8;

FIGS. 10(A) to 10(D) are partial cross-sectional front views illustrating the process of manufacturing a photodetector according to a fourth exemplary embodiment of the present invention;

FIG. 11 is a plan view illustrating the same manufacturing process of FIG. 10;

FIG. 12 is a cross-sectional view illustrating a photodetector according to a fifth exemplary embodiment of the present invention;

FIG. 13 is a cross-sectional view illustrating a photodetector according to a sixth exemplary embodiment of the present invention;

FIG. 14 is a cross-sectional view illustrating a photodetector according to a seventh exemplary embodiment of the present invention;

FIG. 15 is a block diagram illustrating a multilayer optical recording medium reproduction system according to an eighth exemplary embodiment of the present invention, the system including an optical head device;

FIG. 16 is a partial cross-sectional schematic perspective view illustrating the relationship between the multilayer optical recording medium and the optical head device in the same exemplary embodiment;

FIG. 17 is a block diagram illustrating the optical systems and circuits in the optical head device in the same exemplary embodiment;

FIG. 18 is a schematic perspective view illustrating the principle of an astigmatism mechanism used in the same exemplary embodiment;

FIG. 19 is a schematic perspective view illustrating the relationship between a sensor lens, a light shielding plate, and a photodetector in the same exemplary embodiment;

FIG. 20 is a plan view illustrating the relationship between the arrangement of light receiving elements of the photodetector in the same exemplary embodiment and the area irradiated with stray light;

FIG. 21 is a circuit diagram illustrating a circuit that outputs a focus error signal in the same exemplary embodiment;

FIG. 22 is a graph showing the relationship between a position in a width direction at a front focal line and the relative emission intensity of a reflected light beam;

FIG. 23 is a schematic plan view illustrating the relationship between a main window and the beam shapes of main light and stray light at the position of the front focal line in the same exemplary embodiment;

FIG. 24 is a plan view illustrating the focused state of the main beam in the photodetector;

FIG. 25 is an optical arrangement diagram illustrating the positional relationship between the sensor lens, window, and photodetector;

FIG. 26 is a graph showing the relationship between the intensity of an FE signal and a focusing distance for different window widths in the same exemplary embodiment; and

FIG. 27 is a graph showing the relationship between the intensity of a TE signal and the position of a disc for different window widths in the same exemplary embodiment.

### DETAILED DESCRIPTION OF THE PREFERRED EMBODIMENT

Hereinafter, a photodetector according to preferred exemplary embodiments of the present invention, a photodetection system using the same, and a method for manufacturing the photodetector will be described.

### Exemplary Embodiments

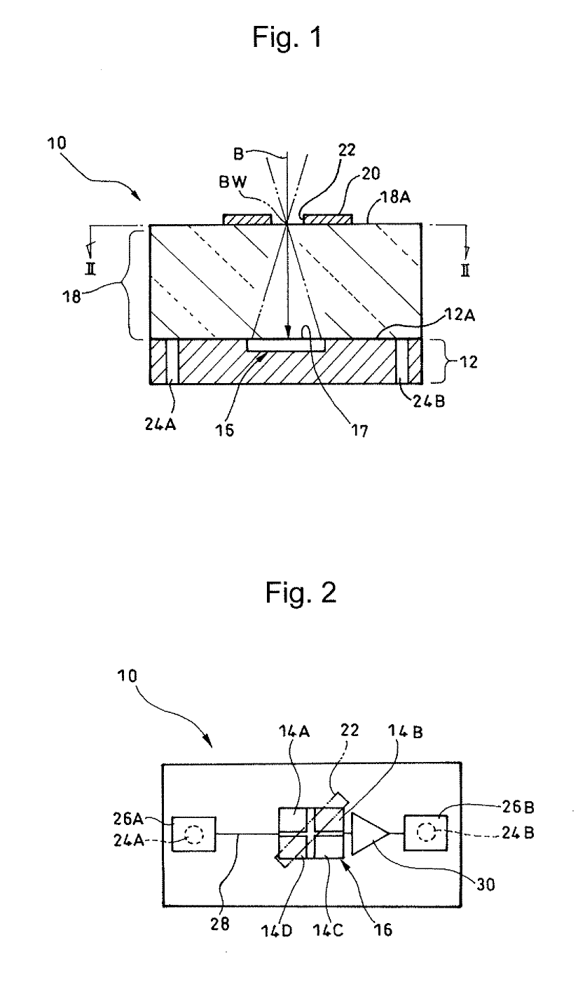

As shown in FIGS. 1 and 2, a photodetector 10 according to a first exemplary embodiment of the present invention is configured to include: a photodetection unit 16 including four photodetection elements 14A, 14B, 14C, and 14D (which may be collectively referred to as photodetection elements 14) that are embedded and arranged in a flat surface (upper surface) 12A of a semiconductor chip 12; a light transmitting unit 18 that is disposed on a light receiving surface 17 side of the photodetection unit 16 (the side thereof opposite to the semiconductor chip 12) so as to cover the photodetection unit 16; a light shielding layer 20 that shields an incident light beam B and is deposited on a surface 18A of the light transmitting unit 18 (the surface on the side opposite to the semiconductor chip 12); and an optical aperture 22 that is provided in the light shielding layer 20 so that the incident light beam B passing through the aperture 22 reaches the photodetection unit 16 through the light transmitting unit 18.

Reference numerals 24A and 24B in FIG. 2 represent through-electrodes that are formed so as to pierce the semiconductor chip 12. Reference numerals 26A and 26B represent electrode pads that are provided on the light transmitting unit 18 side ends of the through-electrodes 24A and 24B, respectively. Reference numeral 28 represents a wiring unit that connects the electrode pads 26A and 26B with the elements of the photodetection unit 16, and reference numeral 30 represents a current-voltage conversion amplifier that is interposed in the wiring unit 28 between the output terminal of the photodetection unit 16 and the electrode pad 26B. In FIG. 2, the wiring unit 28 is illustrated for an example of current output, and a current amplifier may be interposed in the wiring unit 28. Although not shown in FIG. 2, the output of each photodetection element is sent to a corresponding one of the electrode pads through any appropriate one of the wiring unit, the current-voltage conversion amplifier, and, if present, the current amplifier.

The semiconductor chip 12 including the photodetection elements 14 is prepared by forming the photodetection elements by patterning, and the light transmitting unit 18 is formed by depositing a light transmitting resin on the semiconductor chip 12.

A light transmitting resin such as cyclic olefin, acrylic, polycarbonate, or methacrylate is used as the material for the light transmitting unit 18. Such a light transmitting resin is deposited on the semiconductor chip by spin coating or screen printing. Alternatively, a glass plate or the like may be used instead of the light transmitting resin.

The light shielding layer 20 formed on the surface 18A of the light transmitting unit 18 (the surface on the light beam incident side) is formed by depositing a light shielding metal film such as an aluminum, copper, or tungsten film. The optical aperture 22 is formed in advance in the light shielding layer 20 or formed by lithography.

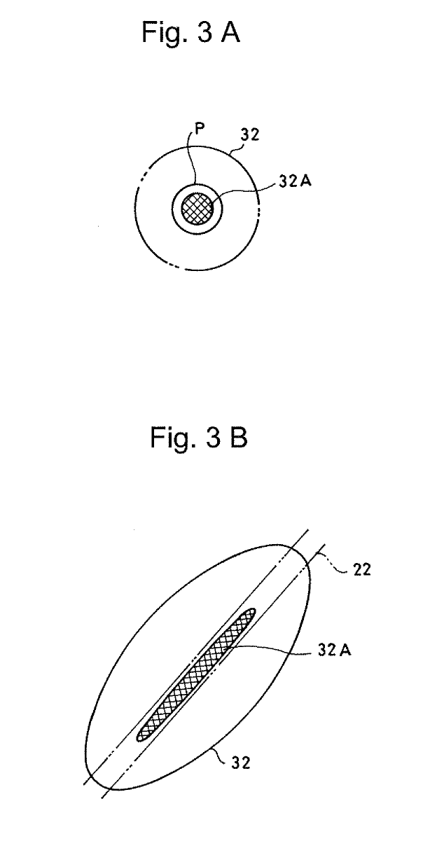

The sizes of the optical aperture 22 and the photodetection unit 16 and the positional relation therebetween are set such that an inner portion 32A of the cross section 32 of an incident light beam passes through the optical aperture 22, as shown in FIGS. 3A and 3B, and that the diverging light beam passing through the optical aperture 22 is projected within the light receiving surface of the photodetection unit 16.

The inner portion is the cross-sectional portion of, for example, a reproduction light beam reflected from a focused recording layer of a multilayer optical recording medium, and stray light, which is the light reflected from an unfocused recording layer, extends over the inner portion and an outside portion therearound. The optical aperture 22 is a pinhole P as shown in FIG. 3A or has, for example, an elongated rectangular (slit-like) shape as shown by a chain double-dashed line in FIGS. 2 and 3B. In either case, it is preferable to dispose the optical aperture at the beam waist where the diameter of the light beam is minimum.

For example, when the optical aperture is a pinhole, the pinhole is disposed at the beam waist BW such as shown by a chain double-dashed line in FIG. 1. When the optical aperture is a slit, the slit is disposed at a position corresponding to a front focal line of the incident light beam that passes through an astigmatic optical element, and the size of the slit is slightly greater than the inner portion 32A of the cross section of the light beam at the front focal line (see the description in the eighth exemplary embodiment for detail).

In the first exemplary embodiment, the optical aperture 22 has a linear slit shape that extends diagonally at an angle of 45° with respect to the four photodetection elements 14A to 14D arranged in a square array so as to cross the central portion thereof, as shown in FIG. 2.

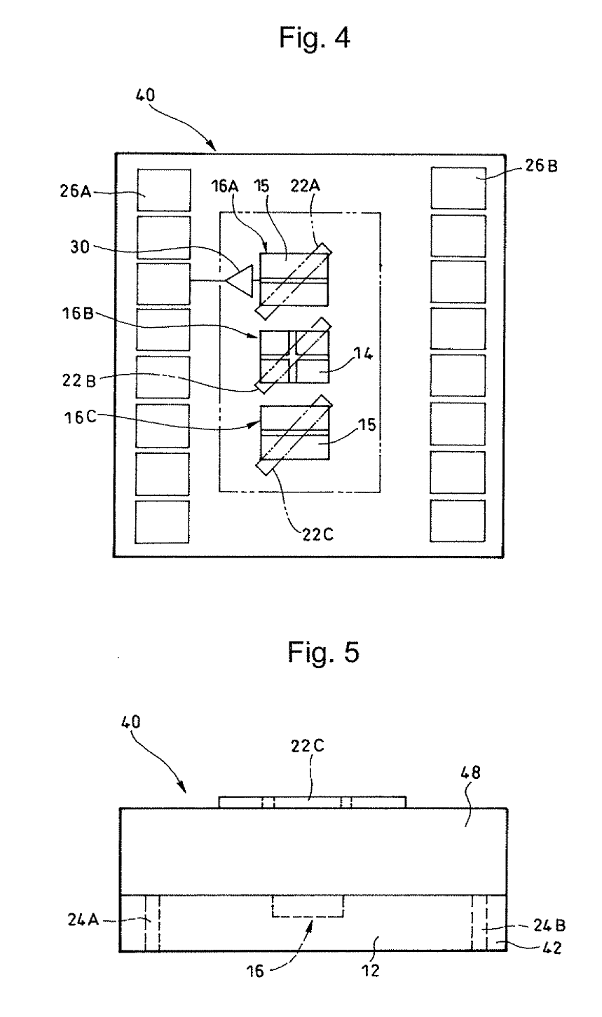

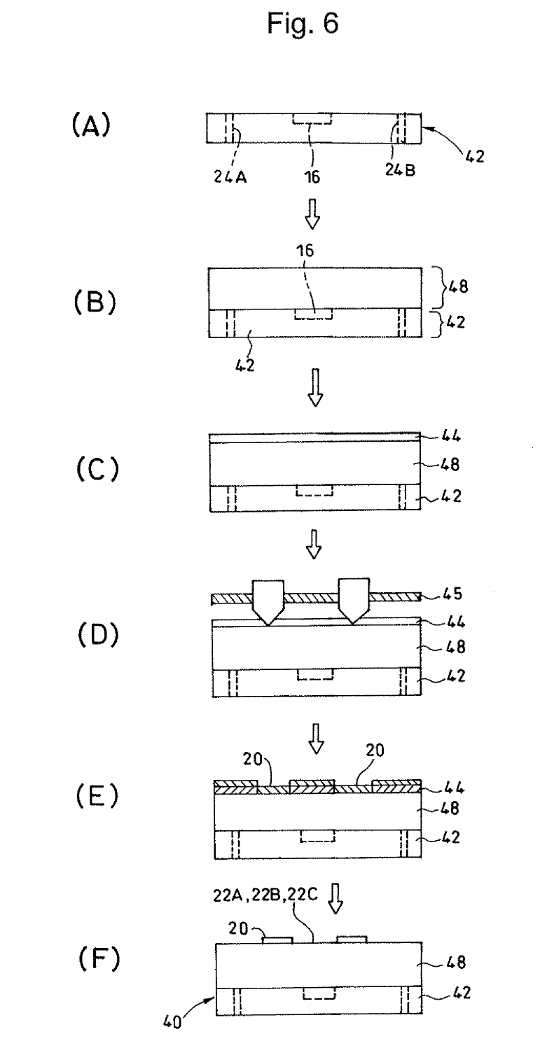

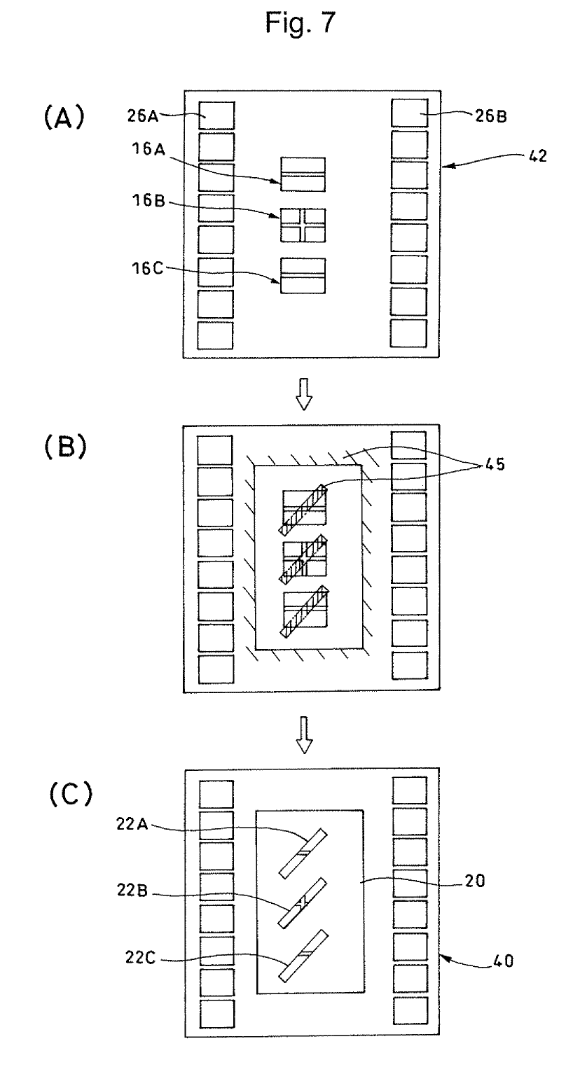

Next, a description will be given of a process of manufacturing a photodetector in a second exemplary embodiment as shown in FIGS. 4 and 5 with reference to FIGS. 6 and 7.

The photodetector 40 manufactured by a method of the second exemplary embodiment includes three photodetection units 16A to 16C and three optical apertures 22A to 22C corresponding to the three photodetection units 16A to 16C.

As shown in FIG. 4, the photodetection unit 16B at the center includes four photodetection elements 14, and each of the photodetection units 16A and 16C on opposite sides includes two photodetection elements 15 arranged vertically in FIG. 4. These photodetection elements 14 and 15 are used for receiving blue light. The optical aperture 22B corresponding to the photodetection unit 16B has a slit-like shape in plan view and is disposed above the center of the four photodetection elements 14 arranged in a square array so as to be inclined upwardly from left to right in FIG. 4 at an angle of 45°. Each of the optical apertures 22A and 22C corresponding to the photodetection units 16A and 16C on opposite sides has a slit-like shape parallel to the optical aperture 22B. In the above-described configuration, each of the photodetection units 16A and 16C includes two photodetection elements 15 arranged vertically but may include four photodetection elements 15 as in the photodetection unit 16B.

Amplifiers 30 are provided for the photodetection elements 14 and 15 of the photodetection units 16A to 16C and interposed in the wiring units between the output terminals of the photodetection elements 14 and 15 and the corresponding electrode pads 26B (in FIG. 4, only the amplifier 30 for one of the photodetection elements of the photodetection unit 16A is shown. The amplifiers for the photodetection units of the other photodetection units are omitted in the figure).

FIGS. 6(A) to 6(F) and 7(A) to 7(C) show manufacturing steps. First, a semiconductor chip 42 is prepared in which three photodetection units 16A to 16C, amplifiers 30, electrode pads 26A and 26B, and through-electrodes 24A and 24B are formed in advance (see FIGS. 6(A) and 7(A)).

Next, as shown in FIG. 6(B), a light transmitting resin such as cyclic olefin, acrylic, polycarbonate, or methacrylate is deposited by spin coating or screen printing so as to cover the surfaces of the photodetection units 16A to 16C, the electrode pads 26A and 26B, and other parts of the semiconductor chip 42, whereby a light transmitting unit 48 is formed.

Next, as shown in FIG. 6(C), a positive photoresist is applied to the light transmitting unit 48 on the side opposite to the semiconductor chip 42 and is pre-baked to form a photoresist layer 44.

Next, as shown in FIGS. 6(D) and 7(B), light is applied to the photoresist layer 44 through a photomask 45 that covers regions corresponding to the optical apertures 22A to 22C, and the photoresist layer 44 is developed, thereby allowing the exposed region of the photoresist layer 44 to be removed.

A light shielding layer 20 is then deposited on the surfaces of the unexposed regions of the photoresist layer 44 and on the naked surface of the light transmitting unit 48 using a light shielding metal material such as aluminum, copper, or tungsten, as shown in FIG. 6(E).

Next, as shown in FIGS. 6(F) and 7(C), the remaining unexposed regions of the photoresist layer 44 are removed (lifted off) together with the light shielding layer deposited thereon.

The unexposed regions of the photoresist layer 44 correspond to the optical apertures 22A to 22C, and therefore the optical apertures 22A to 22C are formed in the light shielding layer 20. In the above process, the light shielding layer 20 is deposited also on regions other than the regions around the photodetection units 16A to 16C.

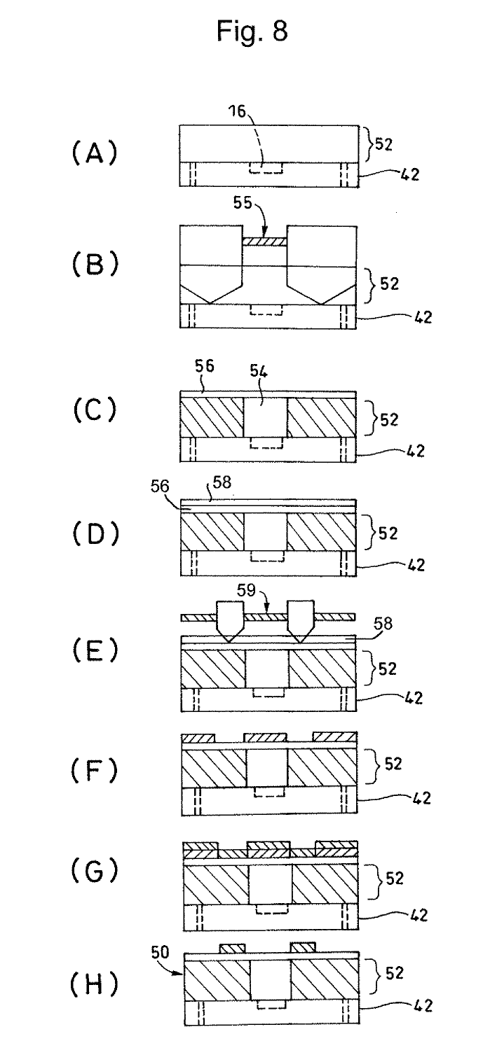

Next, with reference to FIGS. 8(A) to 8(H), a description will be given of a method for manufacturing a photodetector of a third exemplary embodiment. In this photodetector 50, light transmitting units 54 that serve as optical paths for light beams from the optical apertures 22A to 22C to the photodetection units 16A to 16C are formed as light transmitting spaces.

In the manufacturing method in the third exemplary embodiment, a negative photoresist(a first photoresist) is applied to a photodetector semiconductor chip the same as that shown in FIGS. 6(A) and FIG. 7(A) and is pre-baked to form a first photoresist layer 52, as shown in FIG. 8(A).

Next, as shown in FIG. 8(B), light is applied to the photoresist layer 52 through a first photomask 55 that covers regions corresponding to the optical apertures 22A to 22C. The first photoresist layer 52 is then developed, thereby allowing the unexposed regions of the first photoresist layer 52 to be removed, as shown in FIG. 8(C). This process forms the light transmitting units 54 used as the light transmitting spaces and is post-baked to cure the photoresist. The cured first photoresist layer 52 serves as a spacer surrounding the light transmitting units 54.

Next, a light transmitting cover glass 56 is secured onto the exposed region of the first photoresist layer 52 with an adhesive (not shown) so as to cover the light transmitting units 54.

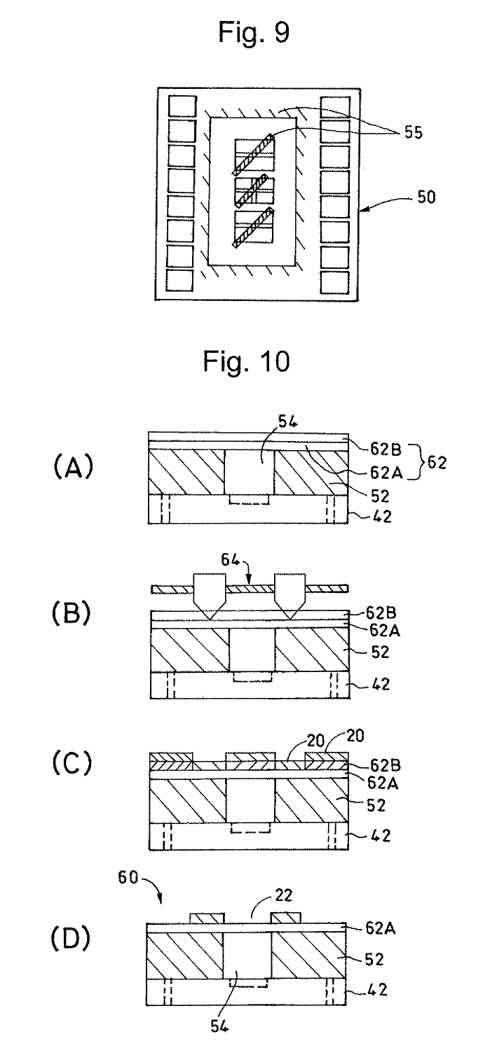

As shown in FIG. 8(D), a positive photoresist (a second photoresist) is then applied to the cover glass 56 and prebaked to form a second photoresist layer 58. Next, as shown in FIGS. 8(E) and 9, the regions corresponding to the optical apertures 22A to 22C are masked with a second photomask 59, and the second photoresist layer 58 is exposed to light.

Next, as shown in FIG. 8(F), the exposed region of the second photoresist layer 58 is removed by development. Then a light shielding layer 20 is deposited on the surfaces of the unexposed regions of the second photoresist layer 58 and on the naked surface of the cover glass 56, as shown in FIG. 8(G).

Finally, as shown in FIG. 8(H), the unexposed regions of the second photoresist layer 58 are removed (lifted off) together with the light shielding layer 20 formed thereon. In this manner, the optical apertures 22A to 22C (see FIG. 7(C)) are formed in the light shielding layer 20, and the photodetector 50 is thereby completed.

Next, a description will be given of a method for manufacturing a photodetector 60 according to a fourth exemplary embodiment with reference to FIGS. 10(A) to 10(D).

The same steps as those shown in FIGS. 8(A) and 8(B) in the third exemplary embodiment are also used in the fourth exemplary embodiment, and the description thereof is omitted.

As shown in FIG. 10(A), a film resist 62 to which a positive photoresist (a second photoresist) is applied is laminated onto the first photoresist layer 52 having the light transmitting units 54 formed therein. This film resist 62 includes a transparent film 62A and a second photoresist 62B applied thereto and is pre-baked directly.

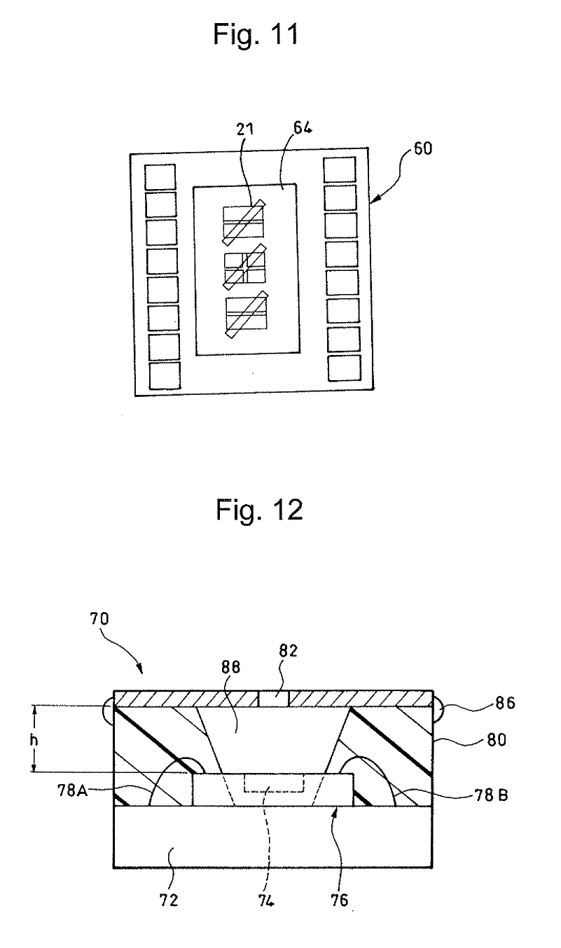

Next, the second photoresist 62B of the film resist 62 is masked with a second photomask 64 shown in FIG. 11 such that regions corresponding to slits 21 are masked, and exposed to light and pre-baked.

The exposed regions of the second photoresist 62B are removed as shown in FIG. 10(C), a light shielding layer 20 formed of a light shielding material is formed on a surface of an unexposed portion of the second photoresist layer and on a naked surface of the transparent film 62A.

Finally, the unexposed regions of the second photoresist 62B are removed together with the light shielding layer 20 formed thereon by development, and the photoresist is post-baked. The transparent film 62A remains unremoved, and the light shielding layer 20 having the optical apertures 22 (22A to 22C) formed therein remains on the transparent film 62A, as shown in FIG. 10(D). In the above process, the transparent film 62A remains present.

In the above exemplary embodiments, the light transmitting units and the light shielding layer are deposited on a single semiconductor chip. However, in practice, a large number of semiconductor chips are formed on a semiconductor wafer. After the light transmitting units and other components are deposited on the semiconductor chips to form a large number of photodetectors, the semiconductor wafer is cut into individual completed semiconductor chips.

In the above exemplary embodiments, the photodetectors with integrated slits are manufactured using fine patterning processes for semiconductors and other materials. However, the present invention can be applied to a case where a photodetector is manufactured using a procedure similar to that used to mount a semiconductor chip on a substrate.

FIG. 12 shows a photodetector 70 of a fifth exemplary embodiment. In this photodetector 70, a semiconductor chip 76 including a photodetection unit 74 is mounted on a substrate 72 and connected to electrodes (not shown) through bonding lead wires 78A and 78B. An annular bonding protection unit 80 made of a resin with the bonding lead wires 78A and 78B embedded therein is formed so as to surround the photodetection unit 74, and a light shielding plate 84 having an optical aperture 82 is mounted on the bonding protection unit 80. The inner space of the annular bonding protection unit 80 serves as a light transmitting unit (light transmitting space) 88. Reference numeral 86 in FIG. 12 represents an adhesive used to secure the light shielding plate to the bonding protection unit. In this exemplary embodiment, the bonding protection unit 80 functions as a spacer, so that the distance h between the photodetection unit 74 and the optical aperture 82 can be maintained with high accuracy.

The optical aperture in the light shielding plate 84 may be formed by making a hole in a thin metal plate using mechanical means or by making a slit or pinhole in a metal plate using electroforming. In the latter case, nickel is used as the material for the light shielding plate 84. The optical aperture may be formed by etching a glass plate. In this case, a high transmittance portion is used as the optical aperture, and a low transmittance portion is used as a light shielding portion. Preferably, a UV curable adhesive is used as the adhesive 86 for securing the light shielding plate.

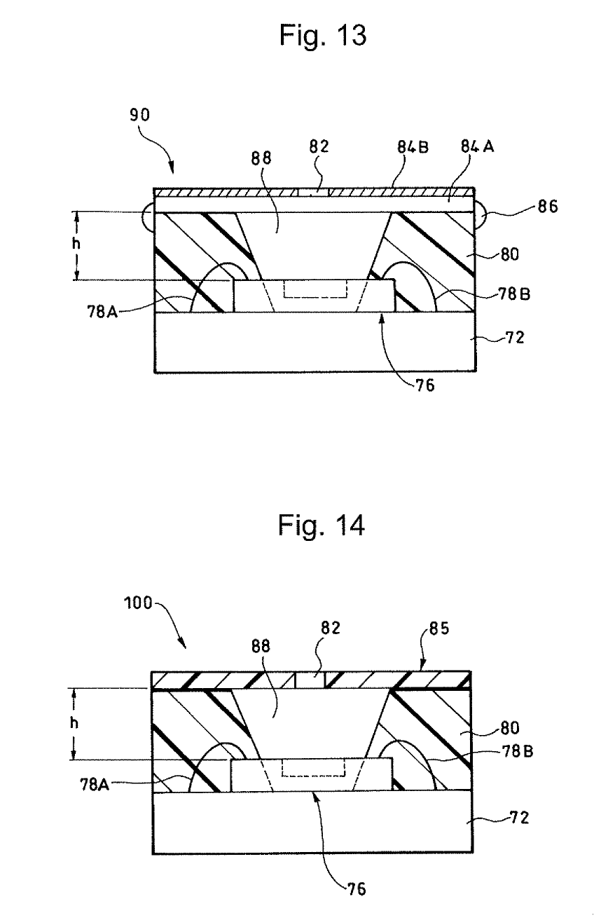

Next, a description will be given of a sixth exemplary embodiment shown in FIG. 13.

In a photodetector 90 in the sixth exemplary embodiment, a light shielding film 84B is deposited on a glass plate 84A that is used instead of the metal-made light shielding plate 84 of the photodetector 70 in the fifth exemplary embodiment above.

In the sixth exemplary embodiment, the light shielding film 84B is deposited on the glass plate 84A by, for example, vapor deposition of chromium, aluminum, or a similar material, and an optical aperture 82 is formed by removing a part of the metal-made light shielding film 84B by etching.

Next, a description will be given of a seventh exemplary embodiment shown in FIG. 14.

In a photodetector 100 according to the seventh exemplary embodiment, a light shielding plate 85 having an optical aperture 82 and formed by molding a resin into shape is used instead of the light shielding plate 84 in the fifth exemplary embodiment or the glass plate 84A and the light shielding film 84B in the sixth exemplary embodiment. Preferably, PPS (polyphenyl polyphenylene sulfide) resin or LCP (liquid crystal polymer) resin suitable for precision molding is used for the light shielding plate 85. The bonding protection unit 80 is bonded to the light shielding plate 85 by welding.

In the above exemplary embodiments, the light transmitting units 18 and 48 are formed so as to cover the amplifiers in wiring units, the electrode pads, and other components, in addition to the photodetection units. However, the present invention can be applied to any cases as long as the light transmitting unit covers at least the photodetection unit.

A description will now be given of an eighth exemplary embodiment for an optical head device including any of the above-described photodetectors and for a photodetection system including the optical head device that is used as a multilayer optical recording medium recording and reproducing system.

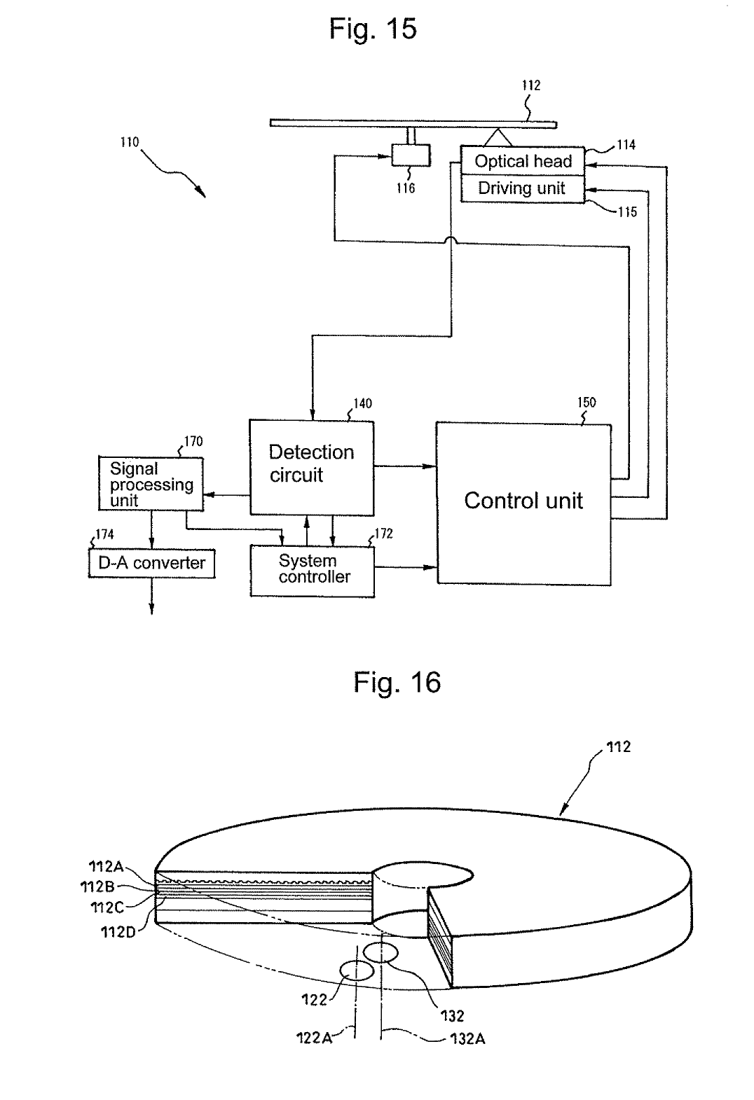

As shown in FIG. 15, the multilayer optical recording medium recording and reproducing system (hereinafter referred to as a recording and reproducing system) 110 according to the eighth exemplary embodiment is configured to include: a multilayer optical recording medium 112; an optical head device (hereinafter referred to as an optical head) 114; a detection circuit 140 that outputs a reproduction (RF) signal, a tracking error (TE) signal, a focus error (FE) signal, and other signals in response to signals from the optical head 114; a control unit 150 that controls, in response to the output signals from the detection circuit 140, the optical head 114, a driving unit 115 that drives the optical head 114 in the radial direction of the multilayer optical recording medium 112, and a spindle motor 116 that rotates the multilayer optical recording medium 112; a signal processing circuit 170 that reproduces a base clock in response to the RF signal from the detection circuit 140 and determines an address; a system controller 172; and a D-A convertor 174.

As shown in FIG. 16, the multilayer optical recording medium 112 includes a plurality of recording layers 112A, 112B, 112C, 112D, etc.

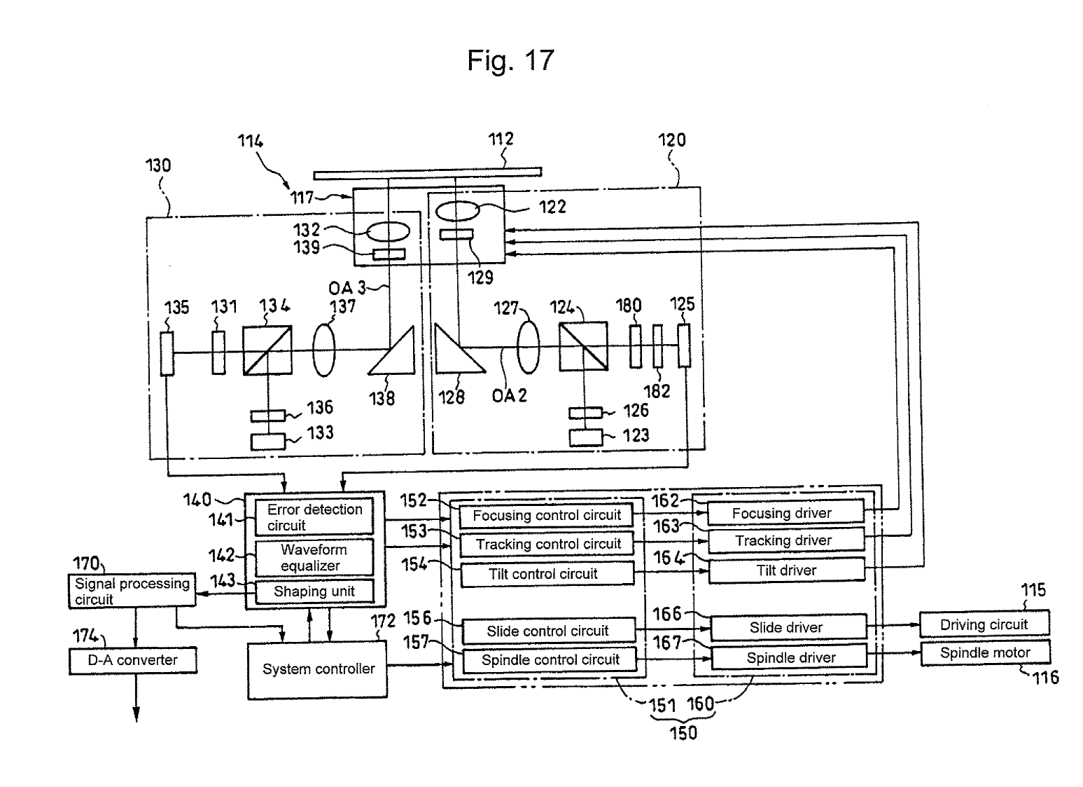

As shown in FIG. 17, the optical head 114 includes a BD optical system 120, a DVD-CD optical system 130, and an actuator 117.

A BD objective lens 122 in the BD optical system 120 and a DVD-CD objective lens 132 in the DVD-CD optical system 130 are installed in the actuator 117 such that central optical axes 122A and 132A of the objective lenses 122 and 132 are arranged on a single radial line orthogonal to the rotation direction of the multilayer optical recording medium 112, as shown in FIG. 16.

The BD optical system 120 is configured to include: a laser light source 123 including a laser diode that emits a laser beam for a Blu-ray disc (trademark); a polarizing beam splitter 124 that reflects, in the horizontal direction in FIG. 17, one of an s-polarized beam and a p-polarized beam in the light beam emitted from the laser light source 123; the above-described BD objective lens 122 that focuses the light beam reflected from the polarizing beam splitter 124 on a specified one of the recording layers in the multilayer optical recording medium 112; and a photodetector 125 that receives a light beam reflected from the multilayer optical recording medium 112 by way of the BD objective lens 122 and the polarizing beam splitter 124. These components are disposed on a common optical axis OA2.

A diffraction grating 126 is disposed on the optical axis OA2 between the laser light source 123 and the polarizing beam splitter 124. A collimating lens 127, a rising mirror 128, and a λ/4 wave plate 129 are disposed in that order between the polarizing beam splitter 124 and the reproduction objective lens 122. A sensor lens 180, which is an astigmatic optical element, is disposed between the polarizing beam splitter 124 and the photodetector 125. A shielding plate (light shielding layer) 182 is disposed between the sensor lens 180 and the photodetector 125.

The collimating lens 127 is movable in the optical axis direction by a driving unit (not shown). The sensor lens 180 is designed such that a predetermined degree of astigmatism is generated in a light beam passing therethrough. This astigmatism is used to detect the focus error signal (FE signal) (more detail will be described later).

The actuator 117 includes, for example, a voice coil motor and is configured to perform a focusing action, a tracking action, and a tilting action in response to a signal from the control unit 150.

The diffraction grating 126 is configured such that the light beam emitted from the laser light source 123 as a linearly polarized diverging light beam is split into one main light beam and two sub-light beams (unless otherwise mentioned, these light beams are referred collectively to as a light beam). The two sub-light beams are used to detect the tracking error signal (TE signal) using a differential push pull method (hereinafter referred to as the DPP method).

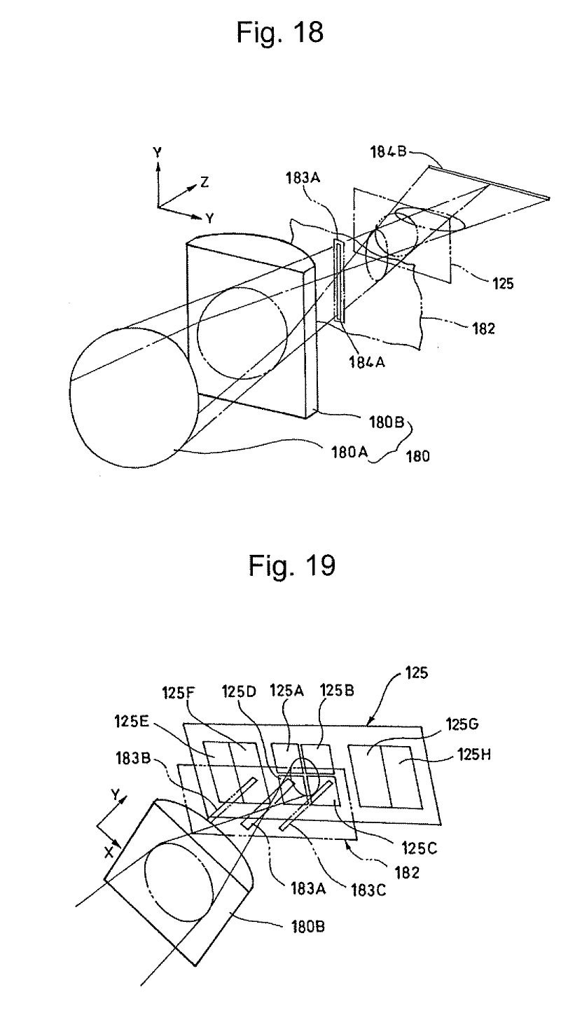

The sensor lens 180 includes a combination of a circular lens 180A and a cylindrical lens 180B and is configured to generate astigmatism in the incident reflected light beam, as shown in FIG. 18 that shows the principle of the astigmatism.

A description will now be given of the principle of the occurrence of astigmatism. In the description, a direction of the optical axis of the reflected light beam is defined as Z direction. A direction in a plane perpendicular to the Z direction is defined as X direction, and a direction orthogonal to the X and Z directions is defined as Y direction.

The sensor lens 180 is designed to generate astigmatism. More specifically, the reflected light beam that has passed through the polarizing beam splitter 124 passes through the circular lens 180A and the cylindrical lens 180B. This light beam is linearly focused in the Y direction at a front focal line 184A which is line-shaped focal point located closer to the cylindrical lens 180B and is also linearly focused in the X direction at a rear focal line 184B which is a line-shaped focal point located further from the cylindrical lens 180B. The photodetector 125 is disposed at a position where the light beam becomes circular.

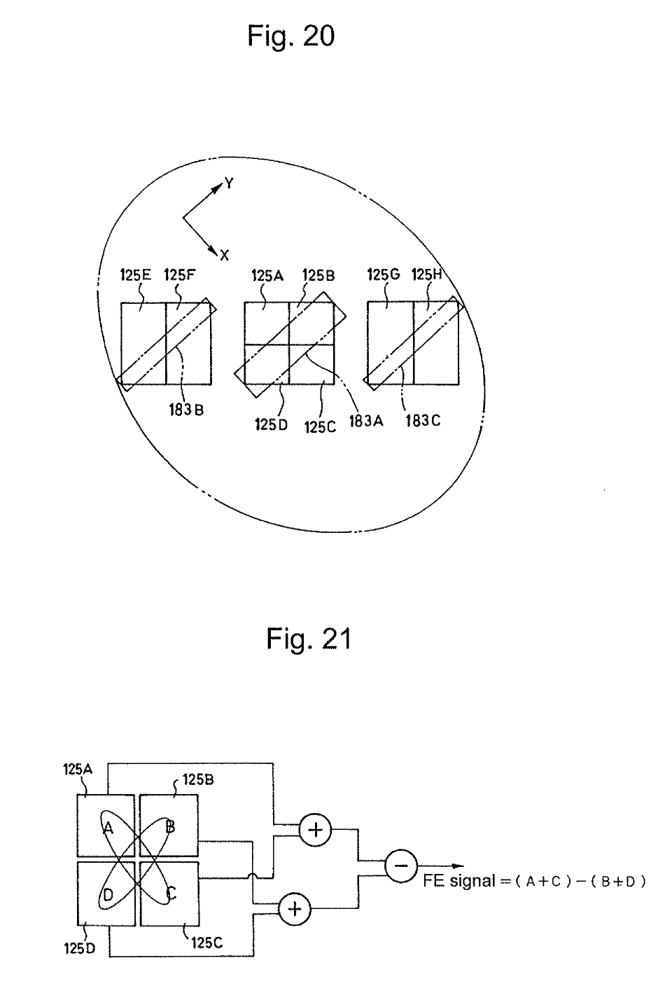

As shown in FIGS. 18 and 20, the shielding plate 182 has optical apertures 183 that are formed at positions corresponding to front focal lines 184A. The optical apertures 183 are slightly larger than the outer shapes of the reflected light beams that form the front focal lines, so that the widthwise outer portions of the reflected light beams (the outer portions in the direction orthogonal to the lengthwise direction in the cross-sectional shapes of the beams) are shielded. The optical apertures 183 include a main window 183A and sub-windows 183B and 183C that are disposed on opposite sides of the main window 183A.

In this exemplary embodiment, the photodetector 125, the optical apertures 183, and the light transmitting spaces (optical paths) therebetween constitute an integrated photodetector similar to any one of the photodetectors in the first to seventh exemplary embodiments. Optical apertures corresponding to the optical apertures 183 in the BD optical system 120 are not provided in the DVD-CD optical system 130.

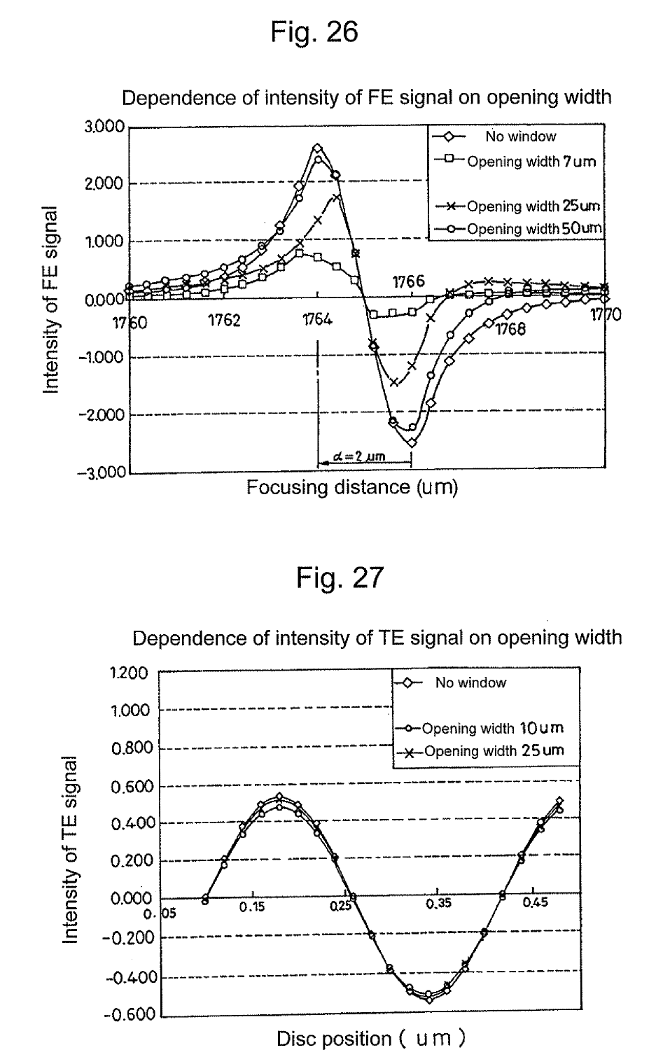

The front focal line 184A is located at a position spaced apart from the light receiving surface of the photodetector 125 by a distance s toward the sensor lens 180 (astigmatic optical element). The distance s is set such that s≅d×M². Here, d is a peak-to-peak distance in an S-shaped curve obtained from the relationship between the focusing distance from the BD objective lens 122 and the FE signal obtained when the reflected light beam enters the photodetector 125 (see FIG. 26), and M is the magnification in the returning path of the optical system from the objective lens 122 to the sensor lens 180.

In this exemplary embodiment, as shown in FIG. 19, the axis lines of the cylindrical lens 180B are inclined 45° clockwise with respect to those shown in FIG. 18 that illustrates the principle.

The windows are optical apertures for limiting the widths of light passing therethrough. The apertures may be holes formed mechanically in a non-light transmitting plate made of metal, resin, glass, or the like. The apertures may be formed by etching a glass plate to form high-transmittance portions and low-transmittance portions. In this case, the high-transmittance portions are used as the apertures to limit the widths of the light passing therethrough.

The main window 183A is provided for the single main light beam that is formed by splitting the light beam from the laser light source 123 by the diffraction grating 126, and the sub-windows 183B and 183C are provided for the two sub-light beams split at the same time.

The front focal line 184A of the main light beam is formed on the optical axis OA2, and the front focal lines of the sub-light beams are formed on opposite sides of the front focal line 184A of the main light beam so as to be parallel to the front focal line 184A.

The photodetector 125 includes four light receiving elements 125A to 125D having the same shape and disposed in four adjacent sections arranged symmetrically in up-down and left-right directions (the up-down direction is defined as a direction inclined 45° with respect to the X and Y directions). As shown in FIG. 21, the difference between the sum of the outputs from a diagonal pair of light receiving elements 125A and 125C and the sum of the outputs from a diagonal pair of light receiving elements 125B and 125D is outputted as a detection signal.

The main window 183A is disposed such that its lengthwise direction coincides with the Y direction.

A first sub-light beam-receiving unit and a second sub-light beam-receiving unit are disposed on opposite sides of the light receiving elements 125A to 125D. The first sub-light beam-receiving unit includes a left-right pair of light receiving elements 125E and 125F having the same shape, and the second sub-light beam-receiving unit includes a left-right pair of light receiving elements 125G and 125H having the same shape and disposed in adjacent two sections. Each sub-light beam-receiving unit may include four light receiving elements disposed in four adjacent sections arranged symmetrically in the up-down and left-right directions.

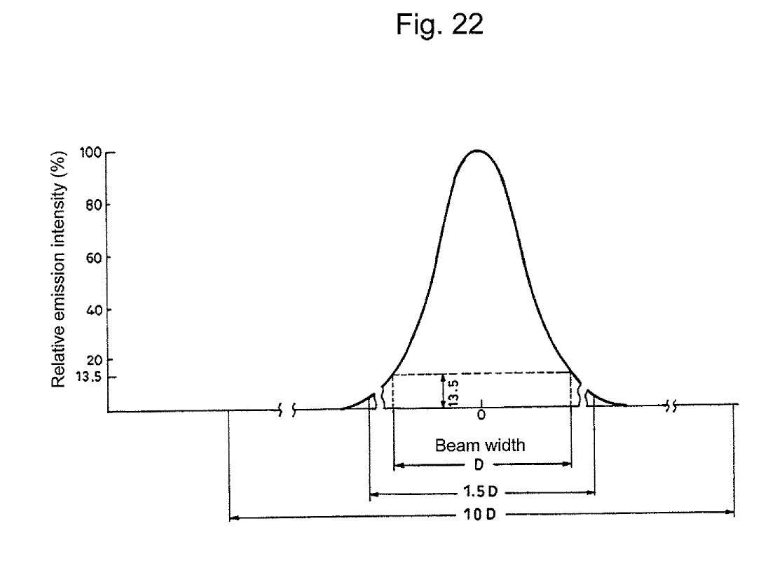

The opening widths of the main window 183A and the sub-windows 183B and 183C (the opening widths in the direction orthogonal to their lengthwise direction) are determined as follows. The intensities of the reflected light beams and sub-light beams at the front focal lines are measured as a function of the position in the opening width direction. Let D be the beam width at 1/e² of the peak value in a relative emitted light intensity distribution curve that represents the relationship between the measured light intensity and the position in the opening width direction (see FIG. 22). Then the widths of the openings are set to 1.50 to 10 D. In the definition typically used, the diameter of a beam is defined as a beam diameter at 1/e² (=0.135) of the peak value of the intensity of the beam.

When the opening width is less than 1.5 D, the area shielded by the shielding plate is too large, so the absolute amount of light necessary for light detection is not obtained. When the opening width exceeds 10 D, stray light cannot be shielded sufficiently, and this results in a reduction in S-N ratio. The present inventor has found that, at the position of the front focal line, the interlayer stray light is expanded outwardly beyond 10 D in the width direction and that the shielding of the interlayer stray light outside the 10 D-wide region is highly effective as measures for stray light.

Under the optical conditions used in this exemplary embodiment, the opening width of the main window 183A is 50 μm or more, and the opening widths of the sub-windows 183B and 183C are 10 μm or more. These values are effective for shielding the stray light without causing any problems with the focus servo pull-in. Preferably, the opening widths are as close to 50 μm and 10 μm as possible.

The DVD-CD optical system 130 has a configuration similar to that of the BD optical system 120. More specifically, a diffraction grating 136, a polarizing beam splitter 134, a collimating lens 137, a rising mirror 138, and a λ/4 wave plate 139 are disposed in that order on a common optical axis OA3 between a laser light source 133 and the DVD-CD objective lens 132. In addition, a photodetector 135 is provided to receive a returning light beam reflected from the multilayer optical recording medium 112 and passing through the polarizing beam splitter 134, and a sensor lens 131 is disposed between the photodetector 135 and the polarizing beam splitter 134. A light shielding plate is not required in the DVD-CD optical system 130.

The detection circuit 140 includes an error detection circuit 141, a waveform equalizer 142, and a shaping unit 143. The control unit 150 includes a control circuit 151 and a driver 160.

The control circuit 151 includes a focusing control unit 152, a tracking control circuit 153, a tilt control circuit 154, a slide control circuit 156, and a spindle control circuit 157.

The driver 161 includes a focusing driver 162, a tracking driver 163, a tilt driver 164, a slide driver 166, and a spindle driver 167.

The control circuit 151 configured as above performs focusing servo control, tracking servo control, slide servo control, and other control operations of the optical head 114 in response to the focus error (FE) signal, the tracking error (TE) signal, and other signals from the detection circuit 140 and also controls the rotation of the spindle motor 116.

The signal processing circuit 170 performs a digital signal processing for reproducing data by subjecting the RF signal from the detection circuit 140 to a processing such as demodulation and error detection-correction, converts the digital signal data to an analog signal through the D-A converter 174, and then supplies the analog signal to an output terminal (not shown).

Next, a description will be given of a process of obtaining a reproduction signal by irradiating the Blu-ray standard multilayer optical recording medium 112 with the light beam emitted from the BD optical system 120.

The laser light source 123 emits a linearly polarized diverging light beam, and the emitted light beam enters the diffraction grating 126 and is split into one main light beam and two sub-light beams as described above.

Each light beam passing through the diffraction grating 126 is reflected from the polarizing beam splitter 124 and then converted to a substantially collimated beam by the collimating lens 127.

After the light beam passes through the collimating lens 127, this light beam is reflected toward the multilayer optical recording medium 112 by the rising mirror 128. The polarization of the light beam is changed from linear to circular by the λ/4 wave plate 129, and the resultant light beam passes through the BD objective lens 122 and is then focused on a target recording layer of the multilayer optical recording medium 112.

The focused light beam is reflected from the target recording layer, and the reflected light beam enters the BD objective lens 122, is converted to a linearly polarized beam by the λ/4 wave plate 129, and enters the polarizing beam splitter 124 by way of the rising mirror 128 and the collimating lens 127. Then the reflected light beam passes through the polarizing beam splitter 124 and enters the photodetector 125 by way of the sensor lens 180 and one of the optical apertures 183 of the shielding plate 182, and the photodetector 125 outputs a reproduction (RF) signal to the detection circuit 140 based on the incident light beam.

In the detection circuit 140, the RF signal is outputted to the signal processing circuit 170 by way of the waveform equalizer 142 and the shaping unit 143. In the signal processing circuit 170, the RF signal is subjected to a digital signal processing such as demodulation and error detection-correction, and the resultant digital signal data is sent to the D-A converter 174. In the D-A converter 174, the digital signal data is converted to an analog signal and supplied to the output terminal.

Also in the DVD-CD optical system 130, recording and reproduction are performed in a similar manner as in the BD optical system 120 except that the target medium is a DVD or CD.

Next, a detailed description will be given of a process of detecting, as a reproduction signal, the reflected light beam that passes through the polarizing beam splitter 124 and enters the photodetector 125 by way of the sensor lens 180 and the shielding plate 182.

When the light beam passes through the sensor lens 180, astigmatism is generated by the sensor lens 180.

As described above, the reflected light beam is focused linearly in the Y direction at the front focal line 184A, which is a line-shaped focal point located closer to the cylindrical lens 180B and is also focused linearly in the X direction at the rear focal line (see reference numeral 184B in FIG. 18), which is a line-shaped focal point located further from the cylindrical lens 180B. The photodetector 125 is disposed at a position where the reflected light beam becomes circular. Therefore, when the outputs from the light receiving elements 125A to 125D are the same, the reflected light beam is focused on a target recording layer. The output from the photodetector 125 can be negative or positive depending on the direction of defocusing, and a so-called S-shaped curve is formed. The focal point can be determined from the S-shaped curve.

Light reflected from a recording layer on which the light beam is not focused can also enters the photodetector 125. More specifically, this light is projected onto a large area surrounding the light receiving surface of the photodetector 125 (for example, the ellipsoidal area shown by a chain double-dashed line in FIG. 20), and this causes noise and reduces the quality of the reproduction signal in conventional products.

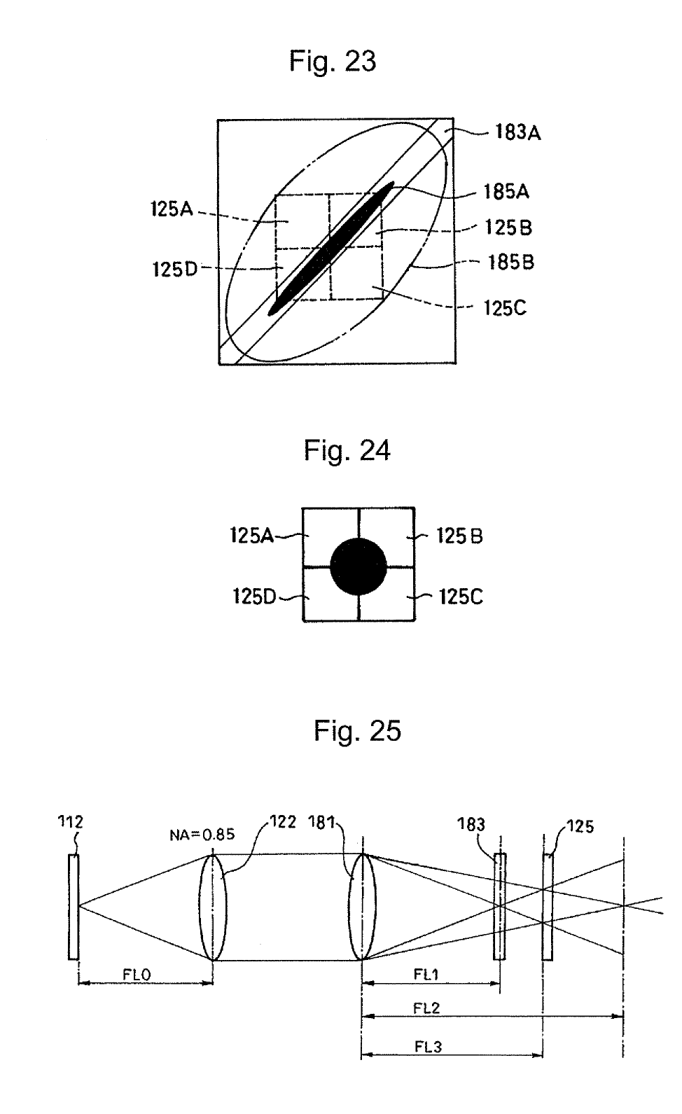

In this exemplary embodiment, the optical apertures 183 are disposed at the positions corresponding to the front focal lines 184A to shield only the stray light from the recording layer at a non-focused position. More specifically, the light beam reflected from the recording layer at the focal point passes through the main window 183A as main light 185A shown in FIG. 23, and stray light 185B outside the main light 185A is shielded by the portions outside the main window 183A of the shielding plate 182.

At the position of the front focal line 184A, the shape and size of the light beam reflected from the recording layer at the non-focused position are like the stray light 185B represented by the chain double-dashed line in FIG. 23. The size of this incident stray light 185B is greater than the size of the main window 183A or, more specifically, than an area including the areas of the light receiving elements 125A to 125D of the photodetector 125.

As shown in FIG. 23, most of the stray light 185B is shielded by the portions outside the main window 183A, and the lengthwise end portions of the stray light 185B lie outside the light receiving elements 125A to 125D and do not cause noise. Therefore, the ratio of the amount of the stray light 185B to the amount of the main light 185A is very small, so that the S-N ratio of the reproduction signal is significantly improved. When the main light 185A is in a focused state, the light reaching the photodetector 125 has a circular beam shape as shown in FIG. 24.

With reference to FIGS. 25 to 27, a description will be given of the reason that the width of the main window 183A is set to 50 μm or more and the widths of the sub-windows 183B and 183C are set to 10 μm or more.

FIG. 25 is a schematic diagram illustrating an optical system including the multilayer optical recording medium 112, the BD objective lens 122, the sensor lens 180, the shielding plate 182, and the photodetector 125. In this schematic diagram, these components are disposed on a linear optical axis.

In FIG. 25, FL0 is the distance between a recording layer of the multilayer optical recording medium 112 and the BD objective lens 122, and FL1, FL2, and FL3 are distances of the shielding plate 182, the rear focal line 184B, and the photodetector 125 from the sensor lens 180. The specifications of an optical head for Blu-ray discs are employed (i.e., the numerical aperture NA of the BD objective lens is 0.85, and the wavelength of the laser beam used is 405 nm), and each of the four light receiving elements 125A to 125D constituting the photodetector 125 has a size of 50 μm×50 μm. Then FL0=1.765 mm, FL1=25.5 mm, FL2=26.475 mm, and FL3=25.978 mm. The distance s between the light receiving surface of the photodetector 125 and the optical apertures 183 is given by FL3−FL1 and is 0.478 mm.

This distance s is close to d×M²=480.5 μm, which is computed from the peak-to-peak distance d (=2 μm) in the FE signal curve in FIG. 26 and the magnification M (=15.5) of the objective lens in the return path. More specifically, s≅d×M².

With the above configuration, the dependence of the intensities of the FE signal and TE signal on the width of the main window was examined.

In FIG. 26, the vertical axis represents the intensity of the FE signal, and the horizontal axis represents the distance (focusing distance) between the BD objective lens 122 and a recording layer. The relationship between the intensity of the FE signal and the focusing distance was determined when the shielding plate was not used and when the window widths were 7 μm, 25 μm, and 50 μm.

As shown in FIG. 27, the dependence of the intensity of the TE signal on the position of the disc was determined for different opening widths (of the sub-windows) (i.e., when the shielding plate was not used and when the opening widths were 10 μm and 25 μm).

The results for the FE signal show that when the opening width is 50 μm or more, the amplitude of the S-shaped curve for the light beam in a focused state is substantially the same as that without the light shielding plate and therefore the focusing servo pull-in can be performed without any problems. The results for the TE signal show that when the widths of the sub-windows are 10 μm or more, the characteristics of the light beam in the focused state are the same as those without the light shielding plate and are not affected by the windows. In the above cases, the widths of the stray light that reaches the light receiving units are substantially the same as the widths of the windows. Therefore, when the opening widths are set to the above sizes, the stray light can be shielded, and the light beams in the focused state are not affected by the opening widths. The above results agree with the range of 1.5 D to 10 D in the relative emission intensity curve at the front focal line shown in FIG. 22.

In the photodetectors of the present invention, the photodetection unit including a plurality of photodetection elements is formed integrally with the light shielding layer having optical apertures. Therefore, the positioning of the photodetection elements and the positioning of the optical apertures can be made in a reliable manner. This allows the photodetector to be easily assembled and also to be manufactured with high accuracy at low-cost.

1. A photodetector, comprising:
a semiconductor chip;
a photodetection unit formed as a part of the semiconductor chip;
a light transmitting unit disposed on a detection side of the at least one photodetection unit; and
a light shielding layer for shielding an incident light beam, the light shielding layer being disposed on the light transmitting unit on a side opposite to the photodetection unit, the light shielding layer having an optical aperture that is formed such that the incident light beam passes therethrough and reaches the photodetection unit through the light transmitting unit, wherein the semiconductor chip, the photodetection unit, the light transmitting unit, and the light shielding layer are formed integrally, and
a size of the optical aperture and a position of the optical aperture relative to the photodetection unit are set such that an inner portion of a cross section of the incident light beam passes through the optical aperture and that the incident light beam having an expanded cross-sectional area is projected within a light receiving surface of the photodetection unit, the expanded cross-sectional area of the incident light beam depending on a thickness of the light transmitting unit.

2. The photodetector according to claim 1, wherein the photodetection unit comprises a plurality of photodetection units, and the optical aperture comprises a plurality of optical apertures that correspond to the plurality of photodetection units.

3. The photodetector according to claim 1, wherein the light transmitting unit is a light transmitting material layer that is deposited so as to cover a surface of the semiconductor chip including the photodetection unit, the light shielding layer is a light shielding material film that is formed on a light incident surface of the light transmitting unit, and the optical aperture is a patterned void space that is formed in the light shielding material film.

4. The photodetector according to claim 1, further comprising a spacer layer that covers a surface of the semiconductor chip except for the photodetection unit, and wherein
the light transmitting unit is a light transmitting space formed in the spacer layer, the light shielding layer is a light shielding material film that is formed on the spacer layer, and the optical aperture is a patterned void space that is formed in the light shielding material film.

5. The photodetector according to claim 4, wherein the spacer layer is a light transmitting material layer that is deposited so as to cover the surface of the semiconductor chip except for the photodetection unit, the light transmitting space is formed by removing a part of the light transmitting material layer, and the void space in the light shielding material film is formed by removing a part of the light shielding material film.

6. The photodetector according to claim 3, wherein the photodetection unit is a photodiode that is formed so as to be embedded in an upper surface of the semiconductor chip.

7. The photodetector according to claim 1, further comprising:
a substrate on which the semiconductor chip is mounted, the photodetection unit being formed as a part of the semiconductor chip disposed on the substrate;
a spacer layer that covers the substrate and a surface of the semiconductor chip except for the photodetection unit; and
a bonding lead wire that electrically connects the semiconductor chip to the substrate, the spacer layer containing the bonding lead wire therein so as to protect the bonding lead wire, and wherein
the light transmitting unit is a light transmitting space surrounded by the spacer layer.

8. A photodetection system, comprising:
a photodetector according to claim 1; and
a detection optical system that guides a reflected light beam from an optical recording medium to the photodetection unit through the optical aperture of the photodetector, wherein
the optical aperture is disposed at a beam waist of the reflected light beam.

9. A method for manufacturing a photodetector having an optical aperture and including a photodetection unit being integral with the optical aperture and a light transmitting unit, a size of the optical aperture and a position of the optical aperture relative to the photodetection unit being set such that an inner portion of a cross section of an incident light beam passes through the optical aperture and that the incident light beam having an expanded cross-sectional area is projected within a light receiving surface of the photodetection unit, the expanded cross-sectional area of the incident light beam depending on a thickness of the light transmitting unit,
the method comprising the steps of:
forming the light transmitting unit by depositing a light transmitting resin or glass on a semiconductor wafer to a thickness equal to a distance between the photodetection unit and the optical aperture, the semiconductor wafer including semiconductor chips each of which includes, on an upper surface thereof, the photodetection unit and an electrode that transmits an output signal from an output terminal of the photodetection unit through a wiring unit, the light transmitting unit being deposited so as to cover at least the photodetection unit;
forming a photoresist layer by applying a photoresist to a surface of the light transmitting unit, the surface of the light transmitting unit being on a side opposite to the photodetection unit;
exposing the photoresist layer to light through a photomask that covers a region corresponding to the optical aperture or a region other than the region of the photoresist layer corresponding to the optical aperture;
removing an exposed portion of the photoresist layer being the region other than the region corresponding to the optical aperture or an unexposed portion of the photoresist layer being the region other than the region corresponding to the optical aperture by development;
forming a light shielding layer made of a light shielding material on the photoresist layer from which the exposed portion has been removed and on a naked surface of the light shielding section or on the photoresist layer from which the unexposed portion has been removed and on a naked surface of the light shielding section;
lifting off and removing the unexposed portion or the exposed portion of the photoresist layer together with the light shielding material formed thereon; and
cutting the semiconductor wafer into the individual semiconductor chips after the light transmitting unit, the light shielding layer and the optical aperture are formed in each semiconductor chip.

10. A method for manufacturing a photodetector having an optical aperture and including a photodetection unit being integral with the optical aperture and a light transmitting unit, a size of the optical aperture and a position of the optical aperture relative to the photodetection unit being set such that an inner portion of a cross section of an incident light beam passes through the optical aperture and that the incident light beam having an expanded cross-sectional area is projected within a light receiving surface of the photodetection unit, the expanded cross-sectional area of the incident light beam depending on a thickness of the light transmitting unit,
the method comprising the steps of:
forming a first photoresist layer having a thickness equal to a distance between the photodetection unit and the optical aperture by applying a first photoresist to a surface of a semiconductor wafer, the surface being opposite to a substrate, the semiconductor wafer including semiconductor chips each of which includes, on an upper surface thereof, the photodetection unit and an electrode that transmits an output signal from an output terminal of the photodetection unit through a wiring unit, a first photoresist layer being deposited so as to cover at least the photodetection unit;
exposing the first photoresist layer to light through a first photomask that covers a region of the first photoresist layer corresponding to the photodetection unit or a region other than the region of the first photoresist layer corresponding to the photodetection unit;
removing an unexposed portion or an exposed portion of the first photoresist layer by development to form a light transmitting space and a spacer layer surrounding the light transmitting space;
providing a light transmitting cover glass layer so as to cover a surface of the spacer layer and the light transmitting space;
forming a second photoresist layer by applying a second photoresist to a surface of the cover glass layer;
exposing the second photoresist layer to light through a second photomask that covers a region of the second photoresist layer corresponding to the optical aperture or, a region other than the region corresponding to the optical aperture;
removing an exposed portion or an unexposed portion of the second photoresist layer by development;
forming a light shielding layer made of a light shielding material on an unexposed portion of the second photoresist layer and on a naked surface of the cover glass layer from which the exposed portion are removed, or, on an exposed portion of the second photoresist layer and on a naked surface of the cover glass layer from which the unexposed portion are removed;
lifting off and removing the unexposed portion or the exposed portion of the second photoresist layer together with the light shielding material formed thereon; and
cutting the semiconductor wafer after a light transmitting unit, the light shielding layer and the optical aperture are formed in each semiconductor chip.

11. A method for manufacturing a photodetector having an optical aperture and including a photodetection unit being integral with the optical aperture and a light transmitting unit, a size of the optical aperture and a position of the optical aperture relative to the photodetection unit being set such that an inner portion of a cross section of an incident light beam passes through the optical aperture and that the incident light beam having an expanded cross-sectional area is projected within a light receiving surface of the photodetection unit, the expanded cross-sectional area of the incident light beam depending on a thickness of the light transmitting unit,
the method comprising the steps of:
forming a photoresist layer having a thickness equal to a distance between the photodetection unit and the optical aperture by applying a first photoresist to a semiconductor wafer, the semiconductor wafer including semiconductor chips each of which includes, on an upper surface thereof, the photodetection unit and an electrode that transmits an output signal from an output terminal of the photodetection unit through a wiring unit, the photoresist layer being deposited so as to cover at least the photodetection unit;
exposing the photoresist layer to light through a first photomask that covers a region corresponding to the photodetection unit;
removing an unexposed portion of the photoresist layer by development to form a light transmitting space and a spacer layer surrounding the light transmitting space;
depositing a film resist so as to cover a surface of the spacer layer and the light transmitting space, the film resist including a film and a second photoresist applied thereto, the film resist being deposited such that the film is in contact with the spacer layer;
exposing only a portion of the film resist to light through a second photomask, the portion of the film resist being a region corresponding to the optical aperture;
removing an exposed portion of the second photoresist of the film resist by development;
forming a light shielding layer made of a light shielding material on a surface of an unexposed portion of the second photoresist layer and on a naked surface of the film;
lifting off and removing the unexposed portion together with the light shielding material formed thereon; and
cutting the semiconductor wafer into the individual semiconductor chips after a light transmitting unit, the light shielding layer and the optical aperture are formed in each semiconductor chip.

12. A photodetection system, comprising:
a laser light source that generates a light beam;
an objective lens that focuses the light beam from the laser light source on an optical recording medium and receives a light beam reflected from the optical recording medium;
an astigmatic optical element that generates astigmatism such that the reflected light beam passing through the objective lens is focused linearly in a Y direction at a front focal line located closer to the objective lens and is also focused linearly in an X direction at a rear focal line located further from the objective lens, the Y direction and the X direction being orthogonal to each other in a plane perpendicular to an optical axis of the reflected light beam, the optical axis being a Z direction; and
a photodetector according to claim 1, wherein
the photodetector is disposed between the front focal line and the rear focal line so as to detect a focal point of the objective lens from a shape of the reflected light beam, and the light shielding layer is disposed at a position of the front focal line so that part of the reflected light beam is shielded, the part of the reflected beam being outside portions thereof in a widthwise direction orthogonal to a lengthwise direction of a cross-sectional shape of the reflected light beam at the front focal line.

13. A photodetection system, comprising:
a laser light source that generates a light beam;
an objective lens that focuses the light beam from the laser light source on an optical recording medium and receives a light beam reflected from the optical recording medium;
an astigmatic optical element that generates astigmatism such that the reflected light beam passing through the objective lens is focused linearly in a Y direction at a front focal line located closer to the objective lens and is also focused linearly in an X direction at a rear focal line located further from the objective lens, the Y direction and the X direction being orthogonal to each other in a plane perpendicular to an optical axis of the reflected light beam, the optical axis being a Z direction; and
a photodetector according to claim 2, wherein
the photodetector is disposed between the front focal line and the rear focal line so as to detect a focal point of the objective lens from a shape of the reflected light beam, and the light shielding layer is disposed at a position of the front focal line so that part of the reflected light beam is shielded, the part of the reflected beam being outside portions thereof in a widthwise direction orthogonal to a lengthwise direction of a cross-sectional shape of the reflected light beam at the front focal line.

14. A photodetection system, comprising:
a laser light source that generates a light beam;
an objective lens that focuses the light beam from the laser light source on an optical recording medium and receives a light beam reflected from the optical recording medium;
an astigmatic optical element that generates astigmatism such that the reflected light beam passing through the objective lens is focused linearly in a Y direction at a front focal line located closer to the objective lens and is also focused linearly in an X direction at a rear focal line located further from the objective lens, the Y direction and the X direction being orthogonal to each other in a plane perpendicular to an optical axis of the reflected light beam, the optical axis being a Z direction; and
a photodetector according to claim 3, wherein
the photodetector is disposed between the front focal line and the rear focal line so as to detect a focal point of the objective lens from a shape of the reflected light beam, and the light shielding layer is disposed at a position of the front focal line so that part of the reflected light beam is shielded, the part of the reflected beam being outside portions thereof in a widthwise direction orthogonal to a lengthwise direction of a cross-sectional shape of the reflected light beam at the front focal line.

15. A photodetection system, comprising:
a laser light source that generates a light beam;
an objective lens that focuses the light beam from the laser light source on an optical recording medium and receives a light beam reflected from the optical recording medium;
an astigmatic optical element that generates astigmatism such that the reflected light beam passing through the objective lens is focused linearly in a Y direction at a front focal line located closer to the objective lens and is also focused linearly in an X direction at a rear focal line located further from the objective lens, the Y direction and the X direction being orthogonal to each other in a plane perpendicular to an optical axis of the reflected light beam, the optical axis being a Z direction; and
a photodetector according to claim 4, wherein
the photodetector is disposed between the front focal line and the rear focal line so as to detect a focal point of the objective lens from a shape of the reflected light beam, and the light shielding layer is disposed at a position of the front focal line so that part of the reflected light beam is shielded, the part of the reflected beam being outside portions thereof in a widthwise direction orthogonal to a lengthwise direction of a cross-sectional shape of the reflected light beam at the front focal line.

16. A photodetection system, comprising:
a laser light source that generates a light beam;
an objective lens that focuses the light beam from the laser light source on an optical recording medium and receives a light beam reflected from the optical recording medium;
an astigmatic optical element that generates astigmatism such that the reflected light beam passing through the objective lens is focused linearly in a Y direction at a front focal line located closer to the objective lens and is also focused linearly in an X direction at a rear focal line located further from the objective lens, the Y direction and the X direction being orthogonal to each other in a plane perpendicular to an optical axis of the reflected light beam, the optical axis being a Z direction; and
a photodetector according to claim 5, wherein
the photodetector is disposed between the front focal line and the rear focal line so as to detect a focal point of the objective lens from a shape of the reflected light beam, and the light shielding layer is disposed at a position of the front focal line so that part of the reflected light beam is shielded, the part of the reflected beam being outside portions thereof in a widthwise direction orthogonal to a lengthwise direction of a cross-sectional shape of the reflected light beam at the front focal line.

17. A photodetection system, comprising:
a laser light source that generates a light beam;
an objective lens that focuses the light beam from the laser light source on an optical recording medium and receives a light beam reflected from the optical recording medium;
an astigmatic optical element that generates astigmatism such that the reflected light beam passing through the objective lens is focused linearly in a Y direction at a front focal line located closer to the objective lens and is also focused linearly in an X direction at a rear focal line located further from the objective lens, the Y direction and the X direction being orthogonal to each other in a plane perpendicular to an optical axis of the reflected light beam, the optical axis being a Z direction; and
a photodetector according to claim 6, wherein
the photodetector is disposed between the front focal line and the rear focal line so as to detect a focal point of the objective lens from a shape of the reflected light beam, and the light shielding layer is disposed at a position of the front focal line so that part of the reflected light beam is shielded, the part of the reflected beam being outside portions thereof in a widthwise direction orthogonal to a lengthwise direction of a cross-sectional shape of the reflected light beam at the front focal line.

18. A photodetection system, comprising:
a laser light source that generates a light beam;
an objective lens that focuses the light beam from the laser light source on an optical recording medium and receives a light beam reflected from the optical recording medium;
an astigmatic optical element that generates astigmatism such that the reflected light beam passing through the objective lens is focused linearly in a Y direction at a front focal line located closer to the objective lens and is also focused linearly in an X direction at a rear focal line located further from the objective lens, the Y direction and the X direction being orthogonal to each other in a plane perpendicular to an optical axis of the reflected light beam, the optical axis being a Z direction; and
a photodetector according to claim 7, wherein
the photodetector is disposed between the front focal line and the rear focal line so as to detect a focal point of the objective lens from a shape of the reflected light beam, and the light shielding layer is disposed at a position of the front focal line so that part of the reflected light beam is shielded, the part of the reflected beam being outside portions thereof in a widthwise direction orthogonal to a lengthwise direction of a cross-sectional shape of the reflected light beam at the front focal line.
